(19) United States
(12) Patent Application Publication
(10) Pub. No.: US 2011/0284046 A1
(43) Pub. Date: Nov. 24, 2011

(54) SEMICONDUCTOR HETEROSTRUCTURE THERMOELECTRIC DEVICE

(76) Inventors: Alexandre M. Bratkovski, Mountain View, CA (US); Leonid Tsybeskov, Newark, NJ (US)

(21) Appl. No.: 13/146,883

(22) PCT Filed: Jan. 29, 2009
(86) PCT No.: PCT/US2009/032447

§ 371 Date: Jul. 28, 2011

(51) Int. Cl. H01L 35/28; H01L 35/14; H01L 35/02

(52) U.S. Cl. 136/203; 136/200; 136/239

(57) ABSTRACT

A semiconductor heterostructure thermoelectric device (101). The semiconductor heterostructure thermoelectric device (101) includes at least one thermoelectric heterostructure unit (110). The thermoelectric heterostructure unit (110) includes a first portion (112) composed of a first semiconductor material and a second portion (114) composed of a second semiconductor material that forms a heterojunction (116) with the first portion (112). The first semiconductor material has a first electrical conductivity and a first thermal conductivity; and, the second semiconductor material has a second electrical conductivity and a second thermal conductivity. The second semiconductor material is disposed as at least one sub-micron patch (244d) of the second portion (114). In addition, the second semiconductor material includes an alloy of the first semiconductor material with an alloying constituent. The dimensionless figure of merit of performance for the semiconductor heterostructure thermoelectric device (101), defined by ZT, is greater than unity.

### TECHNICAL FIELD

Embodiments of the present invention relate generally to the field of thermoelectric devices.

### BACKGROUND

Contemporary microelectronic technology faces a number of critical challenges with the increasing density of integrated circuits. Among these challenges, the removal of heat generated in microprocessors of increasing complexity is most critical.

Similarly, alternative sources of energy are a source of challenging problems for the scientific and technological community. Semiconductors play a significant role in the development of these alternative sources of energy. In particular, photovoltaic devices, such as solar cells, offer great promise for producing new sources of energy. Scientists engaged in the development of ultra-large-scale integration of microelectronic devices and engaged in the development of alternative sources of energy are keenly interested in thermoelectric devices as an alternative means for solving these critical problems. Thermoelectric devices, as thermoelectric coolers, stand at the frontier of microelectronic technology, and, as thermoelectric generators, stand at the frontier of alternative energy research. Thus, research scientists are actively pursuing new technologies for thermoelectric devices that provide a fruitful arena for scientific research and offer great promise for the solution of these problems.

### DESCRIPTION OF THE DRAWINGS

The accompanying drawings, which are incorporated in and form a part of this specification, illustrate embodiments of the invention and, together with the description, serve to explain the embodiments of the invention:

FIG. 1 is a cross-sectional elevation view and schematic of a semiconductor heterostructure thermoelectric device (SHTED) illustrating the functional arrangement of a first portion, a second portion and a heterojunction formed between the first portion and the second portion of the device configured as a thermoelectric generator, in an embodiment of the present invention.

FIG. 2A is a plan view of a SHTED in a partially fabricated state illustrating the functional arrangement of a plurality of sub-micron via-ways in a sacrificial oxide disposed on a substrate, for example, a first portion, which serve to define a plurality of sub-micron patches of a second portion whereat heterojunctions may be formed between the first portion and the second portion of the SHTED, in an embodiment of the present invention.

FIG. 2B is a cross-sectional elevation view along the line delineating cutting plane 2B-2B at an initial stage of fabrication of the partially fabricated SHTED of FIG. 2A illustrating the functional arrangement of the plurality of sub-micron via-ways in the sacrificial oxide disposed on the substrate detailing the location of fences in the sacrificial oxide that serve to isolate adjacent patches from each other, in an embodiment of the present invention.

FIG. 2C is a cross-sectional elevation view at the location of the line delineating cutting plane 2B-2B at a second stage of fabrication of the partially fabricated SHTED illustrating the functional arrangement of a plurality of sub-micron patches of the second portion disposed on the substrate and between fences in the sacrificial oxide detailing the formation of heterojunctions between the first portion and the second portion of the SHTED, in an embodiment of the present invention.

FIG. 2D is a cross-sectional elevation view at the location of the line delineating cutting plane 2B-2B at a third stage of fabrication of the partially fabricated SHTED illustrating the functional arrangement of a top electrode layer on the plurality of sub-micron patches of the second portion, in an embodiment of the present invention.

FIG. 2E is a cross-sectional elevation view at the location of the line delineating cutting plane 2B-2B at a fourth and final stage of fabrication of the SHTED illustrating the functional arrangement of an absorber layer on the SHTED configured as a thermoelectric generator, in an embodiment of the present invention.

FIG. 3 is a perspective view of a SHTED illustrating the functional arrangement of a first portion, a second portion and a heterojunction formed between the first portion and the second portion of the device in at least one nanowire, in an embodiment of the present invention.

FIG. 4 is a perspective view of a SHTED illustrating the functional arrangement of a first portion, a second portion, a third portion, a first heterojunction formed between the first portion and the second portion and a second heterojunction formed between the second portion and the third portion of the device in at least one nanowire, in an embodiment of the present invention.

FIG. 5 is a cross-sectional elevation view of a SHTED illustrating the functional arrangement of portions and heterojunctions in a thermoelectric heterostructure unit of an n-layer of a plurality of n-layers of a multilayer structure, in an embodiment of the present invention.

FIG. 6 is a cross-sectional elevation view and schematic of a SHTED illustrating the functional arrangement of a first portion, a second portion and a heterojunction formed between the first portion and the second portion of the device configured as a thermoelectric cooler, in an embodiment of the present invention.

The drawings referred to in this description should not be understood as being drawn to scale except if specifically noted.

### DESCRIPTION OF EMBODIMENTS

Reference will now be made in detail to the alternative embodiments of the present invention. While the invention will be described in conjunction with the alternative embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be noted that embodiments of the present invention may be practiced without these specific details. In other instances, well known methods, procedures, and components have not been described in detail as not to unnecessarily obscure embodiments of the present invention.

### Physical Description of Embodiments of the Present Invention for a Semiconductor Heterostructure Thermoelectric Device

Embodiments of the present invention include a semiconductor heterostructure thermoelectric device. The semiconductor heterostructure thermoelectric device includes at least one thermoelectric heterostructure unit. The thermoelectric heterostructure unit includes a first portion composed of a first semiconductor material and a second portion composed of a second semiconductor material that forms a heterojunction with the first portion. The first semiconductor material has a first electrical conductivity and a first thermal conductivity; and, the second semiconductor material has a second electrical conductivity and a second thermal conductivity. The second semiconductor material is disposed as at least one sub-micron patch of the second portion. In addition, the second semiconductor material includes an alloy of the first semiconductor material with an alloying constituent. A dimensionless figure of merit of performance for the semiconductor heterostructure thermoelectric device, defined by ZT, is greater than unity.

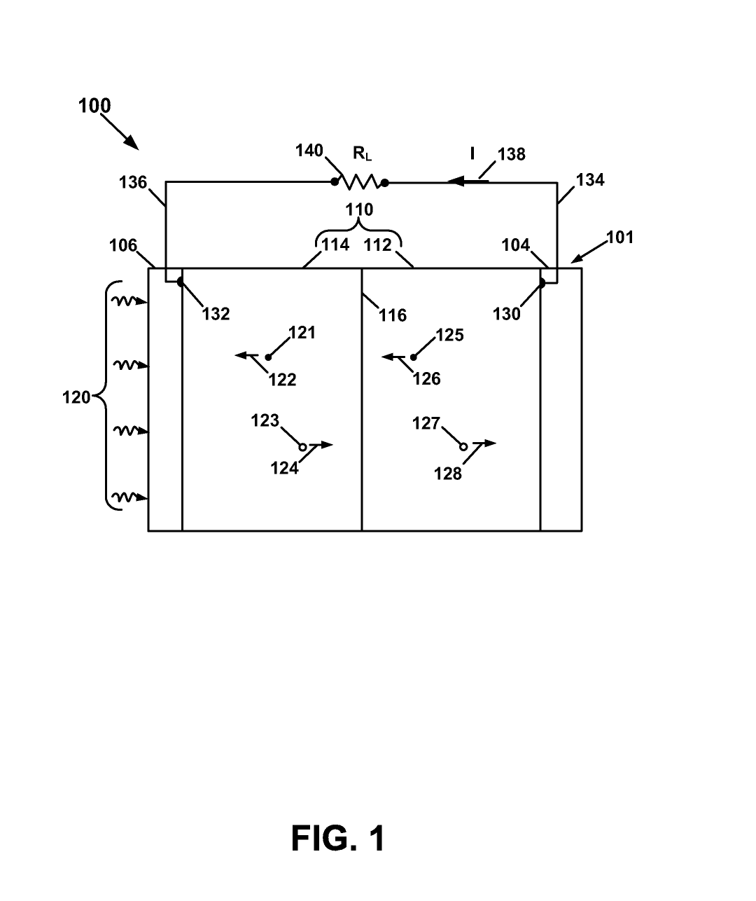

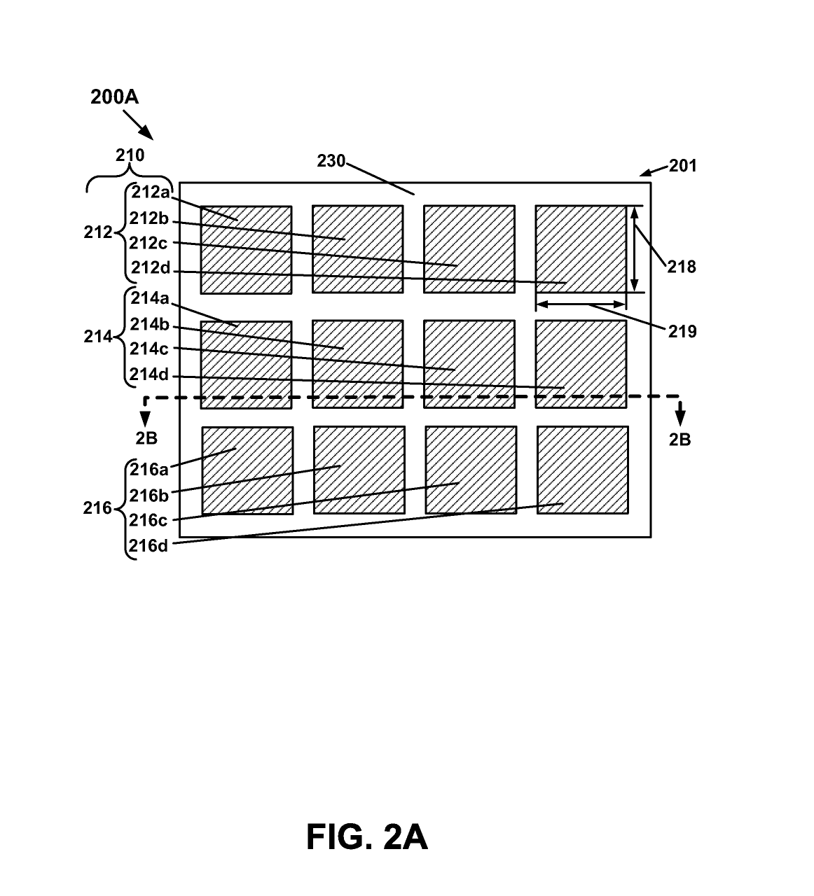

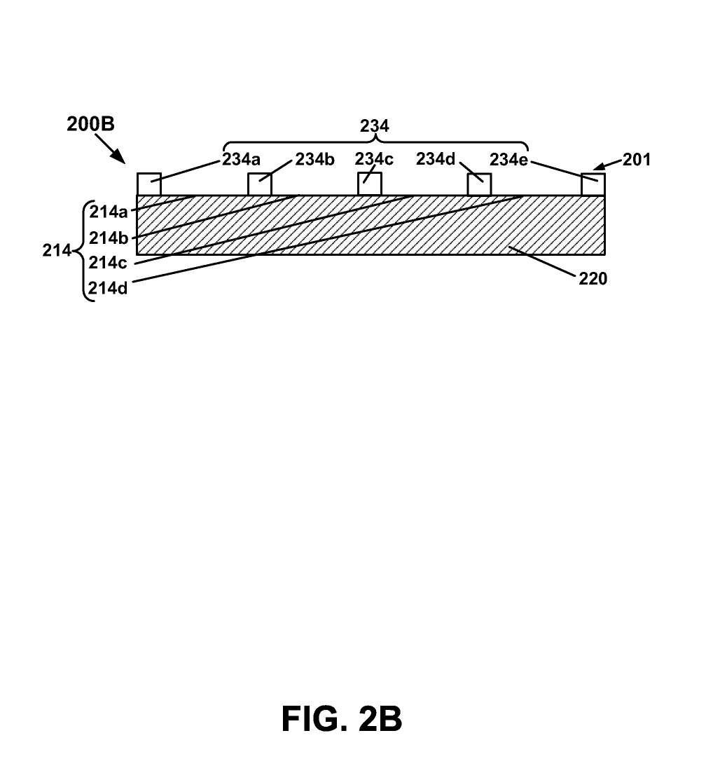

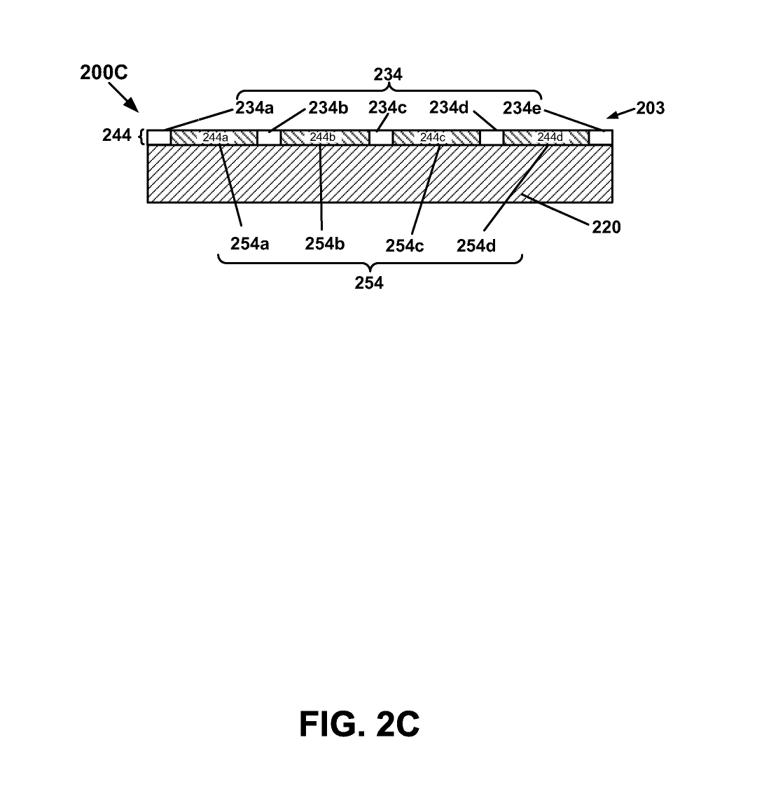

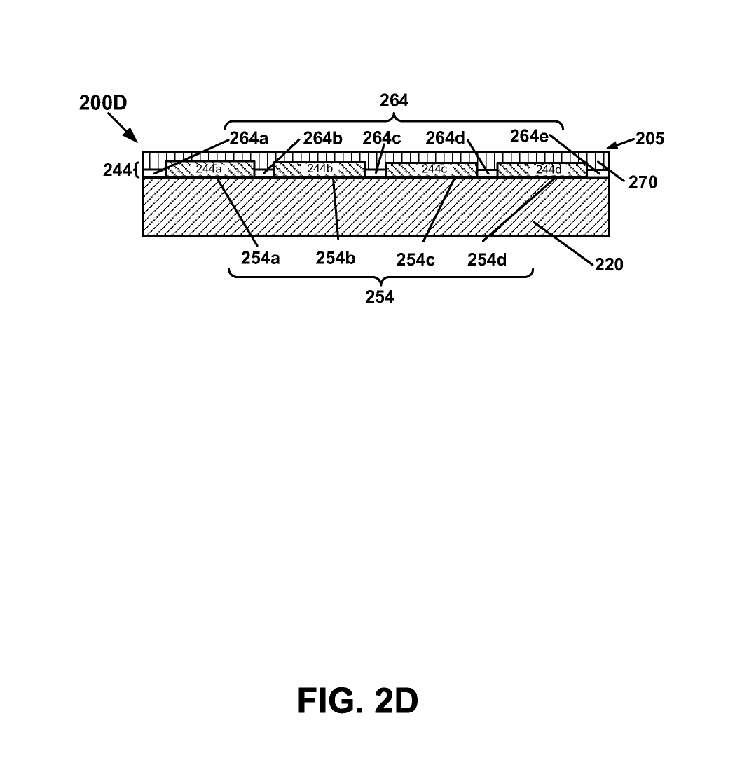

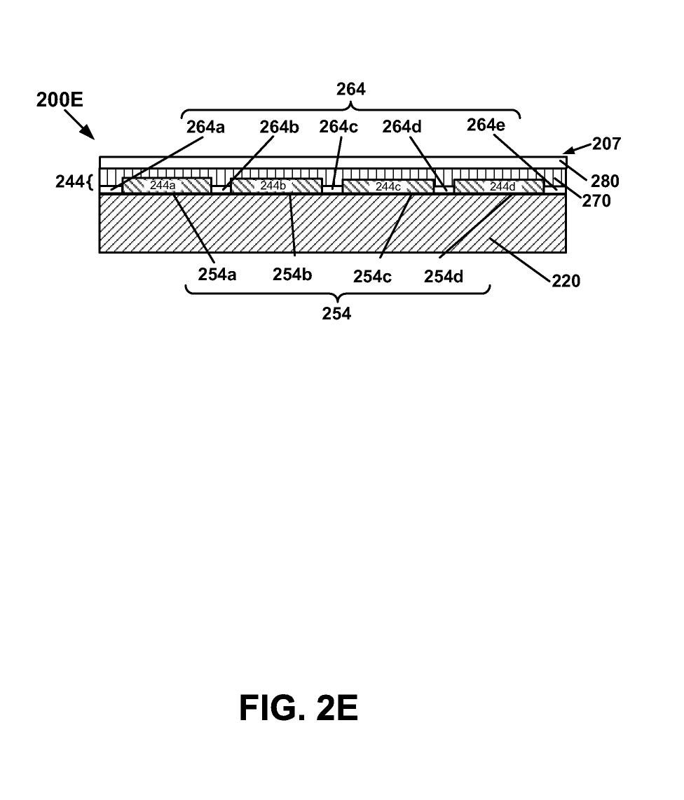

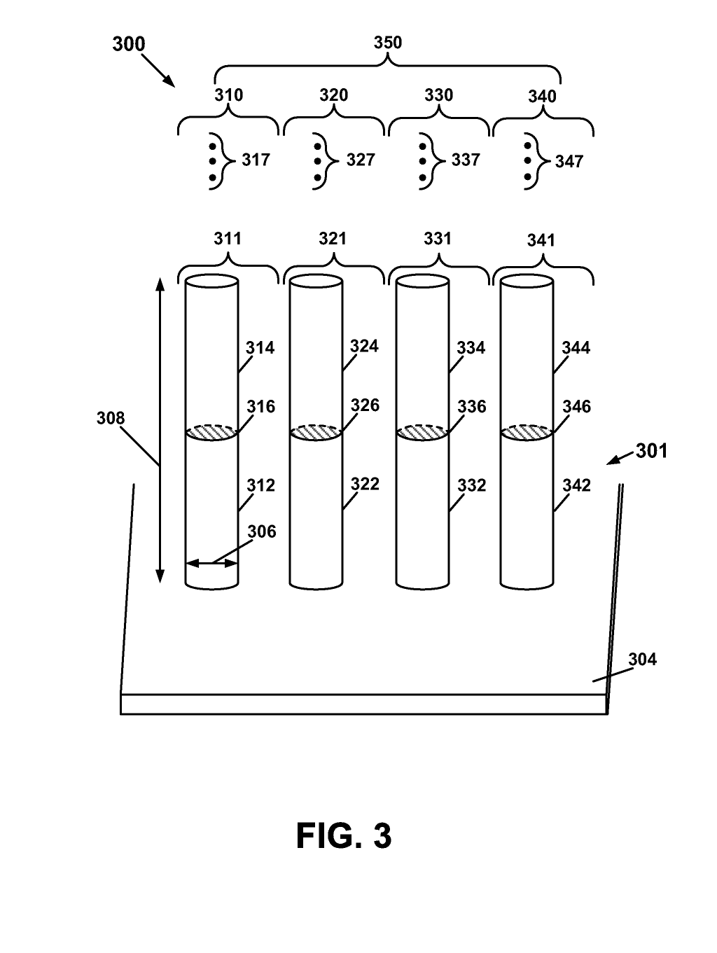

With reference now to FIG. 1, in accordance with an embodiment of the present invention, a cross-sectional elevation view and schematic 100 of a semiconductor heterostructure thermoelectric device (SHTED) 101 is shown. FIG. 1 illustrates the functional arrangement of a first portion 112, a second portion 114 and a heterojunction 116 formed between the first portion 112 and the second portion 114 of the SHTED 101. The SHTED 101 may include at least one thermoelectric heterostructure unit (TEHU) 110 which includes the first portion 112 composed of a first semiconductor material, the second portion 114 composed of a second semiconductor material and the heterojunction 116 formed between the first portion 112 and the second portion 114. The second semiconductor material is disposed as at least one sub-micron patch of the second portion 114, as is subsequently described in greater detail in the discussions of FIGS. 2A-2E. Alternatively, the first semiconductor material may also be disposed as a sub-micron patch of the first portion such that the sub-micron patch of the first portion and the sub-micron patch of the second portion form at least a portion of a nanowire, as is subsequently described in greater detail in the discussions of FIGS. 3, 4 and 5. The dimensionless figure of merit of performance for the SHTED 101, defined by ZT, is greater than unity. As used herein, ZT is a term of art for the dimensionless figure of merit that measures the efficiency of energy conversion from thermal energy to electrical energy of the SHTED 101, which is known in the art. Therefore, Z is a figure of merit of performance for the SHTED 101 that has units of reciprocal temperature. Z is given by:

Z=α²/ρκ_{T}

where α is the Seebeck coefficient of the SHTED 101; T is temperature in Kelvin; ρ is the total electrical resistivity of the SHTED 101, which is the reciprocal of the total electrical conductivity, σ, of the SHTED 101; and, κ_{T} is the total thermal conductivity of the SHTED 101. Thus, ZT is given by:

ZT=α²T/ρκ_{T}

Alternatively, ZT may be given by:

ZT=α²Tσ/κ_{T}.

The first semiconductor material has a first electrical conductivity and a first thermal conductivity; and, the second semiconductor material has a second electrical conductivity and a second thermal conductivity. The second semiconductor material includes an alloy of the first semiconductor material with an alloying constituent.

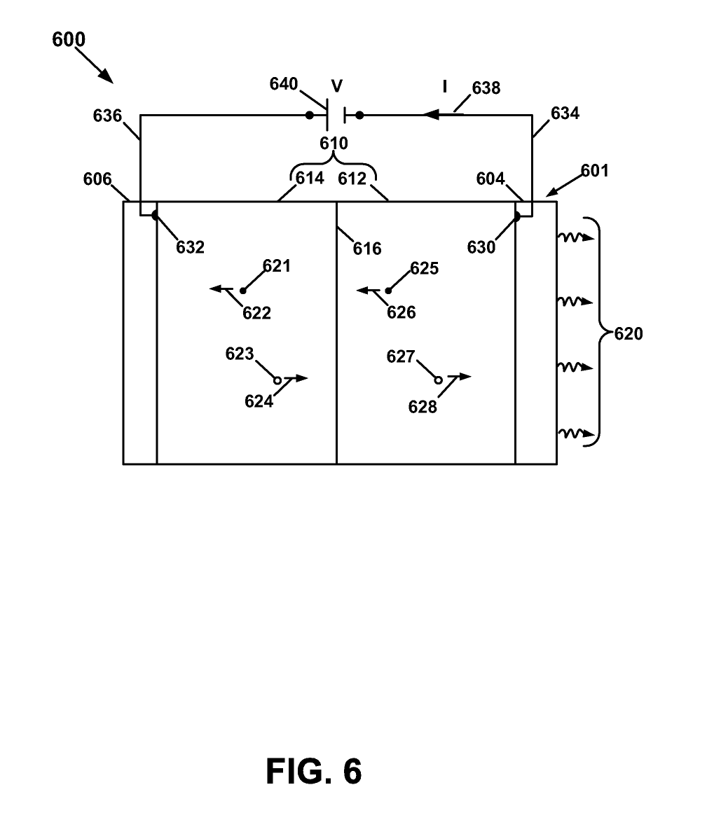

With further reference to FIG. 1 and as shown in FIG. 1, in accordance with an embodiment of the present invention, the SHTED 101 is configured as a thermoelectric generator (TEG). However, embodiments of the present invention are not limited to a SHTED 101 configured as a TEG, rather the SHTED 101 may be configured as a device selected from the group consisting of a TEG and a thermoelectric cooler (TEC), as will later be described in the discussion of FIG. 6. The SHTED 101, configured as a TEG, includes an absorber layer 106, the TEHU 110 and a substrate 104. The absorber layer 106 may be composed of a “black-body” absorbing material, such as a “black-body” polymer, that is disposed on the hot end of the TEHU 110. The substrate 104 is disposed at the cold end of the TEHU 110. As shown in FIG. 1, radiant flux 120, for example, from the Sun at about 100 milliwatts/square centimeter (mW/cm²), that is incident on the absorber layer 106 may raise the temperature of the hot end of the TEHU 110 about 200 degrees centigrade (C) above ambient temperature. For example, in one embodiment of the present invention, the second portion 114 is composed of p+-doped silicon germanium, SiₓGe₁₋ₓ, where x is the atomic fraction of Si in the alloy and 0<x<1. In the p+-doped silicon germanium, SiₓGe₁₋ₓ, the majority carriers are holes and the minority carriers are electrons, for example, electron 121 having an associated electron current 122 and hole 123 having an associated hole current 124. The first portion 112 is composed of intrinsic silicon, Si, in which the carriers may be equal numbers of both holes and electrons, for example, electron 125 having an associated electron current 126 and hole 127 having an associated hole current 128. The increased temperature at the hot end of the TEHU 110 gives rise to a diffusion current of the holes, for example, hole current 124, to the cold end of the TEHU 110. If a first electrical contact 130 is made to the cold end of the TEHU 110 and a second electrical contact 132 is made to the hot end of the TEHU 110, and if a first electrical lead 134 is provided to the cold end of the TEHU 110 and a second electrical lead 136 is provided to the hot end of the TEHU 110, a current 138, I, may be made to flow through a load 140, which has load resistance, R_{L}, without limitation to a resistive load as shown. In one embodiment of the present invention, based on a second portion 114 composed of p+-doped SiₓGe₁₋ₓ, and a first portion 112 composed of Si, the SHTED 101 is compatible with a complementary metal oxide semiconductor (CMOS) process so that it may be used for efficient solid-state cooling of integrated circuits (ICs) as a TEC. In addition, the SHTED 101 based on a second portion 114 composed of p+-doped Siₓ Ge₁₋ₓ, and a first portion 112 composed of Si may be used for power harvesting as a TEG.

With further reference to FIG. 1, in accordance with an embodiment of the present invention, it is seen from the alternative expression for ZT given above that ZT is proportional to the ratio of the total electrical conductivity to the total thermal conductivity. Therefore, there is a competition between electrical carriers and thermal carriers, phonons, for transporting heat from the hot end to the cold end of the TEHU 110. The dimensionless figure of merit, ZT, may be made greater than unity by increasing the total electrical conductivity, σ, and decreasing the total thermal conductivity, κ_{T}. If the second thermal conductivity of the second portion 114 of the TEHU 110 is made sufficiently small, for example, by alloying with a constituent that increases scattering centers for the phonons, then ZT may be made greater than unity. For example, in one embodiment of the present invention, the second portion 114 may be composed of SiₓGe₁₋ₓ, where the Ge provides scattering centers for the phonons. Thus, in an embodiment of the present invention, the second semiconductor material may include an alloy of the first semiconductor material with an alloying constituent such that the second thermal conductivity is less than the first thermal conductivity; for example, the second thermal conductivity may be the thermal conductivity of SiₓGe₁₋ₓ between about 1 and 3 Watt per meter square Kelvin (W/m²K), and the first thermal conductivity may be the thermal conductivity of Si at about 300 W/m²K. The dependence of the thermal conductivity of SiₓGe₁₋ₓ on x is complex and non-linear. Moreover, the first electrical conductivity may be made greater than the second electrical conductivity.

With further reference to FIG. 1, in accordance with an embodiment of the present invention, the first semiconductor material may include an elemental semiconductor material, for example, Si. If the first semiconductor material includes Si, then the second semiconductor material may include an alloy of Si and Ge, for example, SiₓGe₁₋ₓ, where x is the atomic fraction of Si in the alloy. In an embodiment of the present invention, the atomic fraction of Si, x, may be between about 0.60 in 0.40; so, SiₓGe₁₋ₓ, may have a composition between about Si_{0.40}Ge_{0.60} and about Si_{0.60}Ge_{0.40}, but embodiments of the present invention also compositions where the Ge content may be as high as 0.90, or x at about 0.10. In addition, the first semiconductor material may include a semiconductor material doped with at least one doping constituent. Similarly, the second semiconductor material may include an alloy of the first semiconductor material with the alloying constituent such that the second thermal conductivity is less than the first thermal conductivity such that the alloy may also be doped with at least one doping constituent. The first semiconductor material may also include a compound semiconductor material, for example, gallium arsenide, GaAs. If the first semiconductor material includes GaAs, then the second semiconductor material may include an alloy of aluminum, Al, and GaAs, for example, aluminum gallium arsenide, AlₓGa₁₋ₓAs, where x is the atomic fraction of Al in the alloy and 0≦x≦1.

With reference now to FIG. 2A, in accordance with an embodiment of the present invention, a plan view 200A of a partially fabricated SHTED 201 at an initial stage of fabrication is shown. FIG. 2A shows the functional arrangement of a plurality 210 of sub-micron via-ways 212a-212d, 214a-214d and 216a-216d in a sacrificial oxide 230 disposed on a substrate, for example, similar to first portion 112. The plurality 210 of sub-micron via-ways 212a-212d, 214a-214d and 216a-216d serve to define a corresponding plurality of sub-micron patches of the second portion, for example, similar to second portion 114. Heterojunctions may be formed between the first portion, for example, similar to first portion 112, and the second portion, for example, similar to second portion 114, of the partially fabricated SHTED 201. The plurality 210 of sub-micron via-ways 212a-212d, 214a-214d and 216a-216d is shown as a series of rows of via-ways: row 212 includes via-ways 212a-212d; row 214 includes via-ways 214a-214d; and, row 216 includes via-ways 216a-216d. An individual via-way, for example, via-way 214d may be used to define an individual patch, for example, patch 244d shown in FIG. 2C. A via-way, for example, via-way 212d representative of the plurality 210 of sub-micron via-ways 212a-212d, 214a-214d and 216a-216d, may have a rectangular shape, without limitation thereto, with a first side having a length 218 and a second side having a width 219, which defines a corresponding patch replicating the shape of the via-way. As shown in FIG. 2A, via-way 212d has a square shape with length 218 about equal to width 219, which defines a corresponding patch having a square shape. In addition, the dimensions of a via-way, for example, the via-way 214d, are less than 1 micron (μ) to minimize strain in the material of the corresponding patch, for example, patch 244d, in the second portion so that the patches have a submicron size. As shown in FIG. 2A, the plurality 210 of sub-micron via-ways 212a-212d, 214a-214d and 216a-216d may be arranged in a rectangular array. The corresponding patches may be photolithographically defined by dividers, referred to by the term of art “fences,” in the sacrificial oxide 230; the sacrificial oxide 230 may be composed of SiO₂, without limitation thereto. Thus, the plurality of submicron patches may form a checkerboard structure corresponding to the rectangular array of the plurality 210 of sub-micron via-ways 212a-212d, 214a-214d and 216a-216d, as shown in FIG. 2A. To facilitate description of the fabrication of the structure of partially fabricated SHTED 201, the trace of a cutting plane 2B-2B that cuts the lower portion of the row 214 through via-ways 214a-214d is shown, which is further described in the discussion of the next figure, FIG. 2B.

With reference now to FIG. 2B, in accordance with an embodiment of the present invention, a cross-sectional elevation view 200B along the line delineating cutting plane 2B-2B of the partially fabricated SHTED 201 of FIG. 2A at an initial stage of fabrication is shown. FIG. 2B illustrates the functional arrangement of the plurality 210 of FIG. 2A of sub-micron via-ways 214a-214d in the row 214 in the sacrificial oxide 230 of FIG. 2A disposed on a substrate 220. FIG. 2B details the location of the fences in the sacrificial oxide 230 of FIG. 2A that serve to partition and to define the shape of adjacent patches from each other. A plurality 234 of fences 234a-234e defines the sub-micron size via-ways 214a-214d of row 214 in communication with the substrate 220. In one embodiment of the present invention, the substrate, for example, similar to first portion 112, may be a wafer composed of p-type doped Si. Subsequently, the second semiconductor material of the second portion, for example, second portion 114, is deposited onto the regions of the substrate 220 defined by the via-ways, for example, via-ways 214a-214d, to form a plurality of patches, for example, plurality 244 of sub-micron patches 244a-244d, which is further described in the discussion of the next figure, FIG. 2C.

With reference now to FIG. 2C, in accordance with an embodiment of the present invention, a cross-sectional elevation view 200C at the location of the line delineating cutting plane 2B-2B of a partially fabricated SHTED 203 at a second stage of fabrication is shown. FIG. 2C illustrates the functional arrangement of a plurality 244 of sub-micron patches 244a-244d of the second portion, for example, second portion 114, disposed on the substrate 220, for example, first portion 112, and between fences 234a-234e in the sacrificial oxide 230 of FIG. 2A. FIG. 2C details the formation of a plurality 254 of heterojunctions 254a-254d between the first portion and the second portion of the partially fabricated SHTED 203. In one embodiment of the present invention, the plurality 244 of sub-micron patches 244a-244d may be composed of SiₓGe₁₋ₓ so that there is a mismatch of lattice parameter between the underlying substrate 220, for example, a first portion composed of a first semiconductor such as Si. This gives rise to a strain in the SiₓGe₁₋ₓ of the second portion which may be relieved in an embodiment of the present invention, which is further described in the discussion of the next figure, FIG. 2D.

With reference now to FIG. 2D, in accordance with an embodiment of the present invention, a cross-sectional elevation view 200D at the location of the line delineating cutting plane 2B-2B of a partially fabricated SHTED 205 at a third stage of fabrication is shown. FIG. 2D illustrates the functional arrangement of a top electrode layer 270 on the plurality 244 of sub-micron patches 244a-244d of the second portion, for example, second portion 114. The strain in the SiₓGe₁₋ₓ of the second portion may be relieved by etching away the fences of the sacrificial oxide, SiO₂, and annealing the plurality 244 of sub-micron patches 244a-244d composed of SiₓGe₁₋ₓ. The annealing relaxes the strain due to the lattice misfit so that the plurality 244 of sub-micron patches 244a-244d composed of SiₓGe₁₋ₓ are almost defect free. This procedure for fabricating a SHTED is desirable because defects, such as dislocations, may damage the performance of the SHTED that relies on band-structure engineering and an abrupt interface between a first portion, substrate 220, for example, a Si substrate, and an overlayer of the second portion, for example, a SiₓGe₁₋ₓ overlayer. Therefore, embodiments of the present invention for fabricating the SHTED are distinguished from other structures known in the art, for example, which use continuous layers of (SiₓGe₁₋ₓ)_{1-y}C_{y}, where y is the atomic fraction of carbon, C, and 0≦y≦1, in which C is added to contract the lattice of a (SiₓGe₁₋ₓ)_{1-y}C_{y} overlayer to bring the lattice of the (SiₓGe₁₋ₓ)_{1-y}C_{y} overlayer into registry with the lattice of a Si substrate. It should be recognized that the use of C may give rise to a tendency to form silicon carbide, SiC, due to C segregation to the heterojunction, which may kill device performance, especially at elevated temperatures of SHTED operation, viz. 160-200 degree C. As shown in FIG. 2D, a plurality 264 of isolation oxides 264a-264e may be fabricated around the plurality 244 of sub-micron patches 244a-244d. Subsequently, the top electrode layer 270 may be fabricated on and electrically coupled with the plurality 244 of sub-micron patches 244a-244d. In one embodiment of the present invention, the top electrode layer 270 may be composed of p+-doped Si.

With reference now to FIG. 2E, in accordance with an embodiment of the present invention, a cross-sectional elevation view 200E at the location of the line delineating cutting plane 2B-2B of a SHTED 207 at a fourth and final stage of fabrication is shown. FIG. 2E illustrates the functional arrangement of an absorber layer 280 on the SHTED 207 configured as a TEG. After the top electrode layer 270 is fabricated on the plurality 244 of sub-micron patches 244a-244d, the absorber layer 280 may be deposited on the top electrode layer 270 to increase the thermal absorption from a source of heat, for example, the sun. The absorber layer 280 may be composed of a blackening material, for example, carbon black, a blackening layer or a die. A first electrical contact to a first electrical lead, similar to first electrical contact 130 to first electrical lead 134, may then be made to the substrate 220, which may serve as a bottom electrode for the TEG. Similarly, a second electrical contact to a second electrical lead, similar to second electrical contact 132 to second electrical lead 136, may then be made to top electrode layer 270 for the TEG. Thus, SHTED 207 may be configured to supply current to a load similar to SHTED 101 shown in FIG. 1. Alternatively, a SHTED 207 may be configured as a TEC similar to SHTED 601 shown in FIG. 6.

With reference now to FIG. 3, in accordance with an embodiment of the present invention, a perspective view 300 of a SHTED 301 illustrating the functional arrangement a first portion 312, a second portion 314 and a heterojunction 316 formed between the first portion 312 and the second portion 314 of SHTED 301 in at least one nanowire 310 is shown. The SHTED 301 includes at least one nanowire 310 including at least one TEHU 311. The nanowire 310 is disposed on a substrate 304. The TEHU 311 includes the first portion 312 composed of a first semiconductor material, the second portion 314 composed of a second semiconductor material and the heterojunction 316 formed between the first portion 312 and the second portion 314. The first portion 312 has a first band gap and the second portion 314 has a second band gap. The first band gap of the first portion 312 is different from the second band gap of the second portion 314. The second portion 314 includes a second semiconductor material that includes an alloy of the first semiconductor material with an alloying constituent. For example, if the first semiconductor material is Si, and the second semiconductor material is an alloy of Si and Ge, for example, SiₓGe₁₋ₓ, then the band gap of Si, which is 1.12 electron-volts (eV), is greater than the band gap of SiₓGe₁₋ₓ, which depends on the fraction, x, of Si in the alloy and lies between 1.12 eV at high Si content and the band gap of Ge, which is about 0.7 eV, at low Si content. In an embodiment of the present invention, the dimensionless figure of merit of performance for the at least one TEHU 311 of the nanowire 310, defined by ZT, is greater than unity. The first semiconductor material has a first electrical conductivity and a first thermal conductivity; and, the second semiconductor material has a second electrical current activity and a second thermal conductivity. Similar to the description above of FIG. 1, if the second thermal conductivity of the second portion 314 of the nanowire 310 is made sufficiently small, for example, by alloying with a constituent that increases scattering centers for the phonons, then ZT may be made greater than unity. For example, in one embodiment of the present invention, the second portion 314 may be composed of SiₓGe₁₋ₓ, where the Ge provides scattering centers for the phonons. Thus, in an embodiment of the present invention, the second semiconductor material may include an alloy of the first semiconductor material with an alloying constituent such that the second thermal conductivity is less than the first thermal conductivity. Thus, the first semiconductor material may include an elemental semiconductor material, for example, Si. If the first semiconductor material includes Si, then the second semiconductor material may include an alloy of Si and Ge, for example, SiₓGe₁₋ₓ. The first semiconductor material may also include a compound semiconductor material, for example, gallium arsenide, GaAs. If the first semiconductor material includes GaAs, then the second semiconductor material may include an alloy of aluminum, Al, and GaAs, for example, aluminum gallium arsenide, AlₓGa₁₋ₓAs.

With further reference to FIG. 3, in accordance with an embodiment of the present invention, the nanowire 310 may include additional thermoelectric heterostructure units (TEHUs) 317, indicated by the ellipsis labeled 317. A plurality of TEHUs includes TEHU 311 in combination with TEHUs 317. The additional TEHUs 317 may be disposed one on top of the other to extend the length of the nanowire 310 along the direction indicated by double-headed arrow, labeled 308, showing the length of the single TEHU 311. The additional TEHUs 317 may replicate the structure of TEHU 311 described above, but without limitation thereto, as the additional TEHUs 317 may have alternative structures. Moreover, SHTED 301 may include a plurality 350 of nanowires. As shown in FIG. 3, the plurality 350 of nanowires includes, without limitation thereto: nanowire 310, nanowire 320, nanowire 330 and nanowire 340. Nanowire 320 includes at least one TEHU 321; the TEHU 321 includes a first portion 322 composed of a first semiconductor material, a second portion 324 composed of a second semiconductor material and a first heterojunction 326 formed between the first portion 322 and the second portion 324. The nanowire 320 may include additional TEHUs 327, indicated by the ellipsis labeled 327. Similarly, nanowire 330 includes at least one TEHU 331; the TEHU 331 includes a first portion 332 composed of a first semiconductor material, a second portion 334 composed of a second semiconductor material and a first heterojunction 336 formed between the first portion 332 and the second portion 334. The nanowire 330 may include additional TEHUs 337, indicated by the ellipsis labeled 337. In addition, nanowire 340 includes at least one TEHU 341; the TEHU 341 includes a first portion 342 composed of a first semiconductor material, a second portion 344 composed of a second semiconductor material and a first heterojunction 346 formed between the first portion 342 and the second portion 344. The nanowire 340 may include additional TEHUs 347, indicated by the ellipsis labeled 347. The additional nanowires, for example, nanowires 320, 330 and 340, may replicate the structure of nanowire 310 as described above, but without limitation thereto. The additional nanowires, for example, nanowires 320, 330 and 340, are likewise disposed on substrate 304. Although the nanowires are shown as being disposed in a linear array, embodiments of the present invention are not so limited, as the plurality 350 of nanowires may form a three dimensional structure, for example, with additional nanowires (not shown) into the depth of FIG. 3. In addition, the top surfaces of the plurality 350 of nanowires may be provided with an absorber layer (not shown in FIG. 3), similar to absorber layer 106 shown in FIG. 1.

With further reference to FIG. 3, in accordance with an embodiment of the present invention, the TEHU 311 has a diameter 306, which is also the diameter of the nanowire 310. The TEHU 311 also has a length 308. The mean free path of the electron is on the order of 1 nanometer (nm) and the mean free path of the phonon is on the order of 100 nm The diameter of the TEHU 311 is greater than 1 nm but less than 100 nm For example, if the diameter of the TEHU 311 is on the order of 10 to 60 nm, phonons are strongly scattered, for example, by the sidewalls of the TEHU 311, but the electrons go through TEHU 311 relatively unimpeded compared with the phonons. Under these circumstances, the thermal conductivity of the TEHU 311 and correspondingly the nanowire 310 including at least one TEHU, for example, TEHU 311, will be greatly diminished compared with the electrical conductivity of the TEHU 311 and correspondingly the nanowire 310. Moreover, the nanowire 310 including at least one TEHU 311 will have a further diminished thermal conductivity beyond the effect of the diameter of the nanowire 310 for scattering phonons due to the structure of the TEHU 311 including the second portion 314 composed of an alloy that further diminishes the thermal conductivity of the TEHU 311 and correspondingly the nanowire 310 including TEHU 311. Therefore, in an embodiment of the present invention, the dimensionless figure of merit ZT is further improved by a structure including nanowires having a critical diameter small enough to impede phonon transport without substantially hindering electron transport, but further including at least one TEHU, for example, TEHU 311, including a second portion 314 composed of an alloy that further diminishes the thermal conductivity, as described above. The critical diameter of the nanowire to obtain this diminution of thermal conductivity, for example, nanowire 310, is between about 1 nm and 100 nm In addition, the nanowire, for example, nanowire 310, can be grown to an overall length of about 1 to 2 micrometers (μm), a micrometer being equal to 1000 nm

With further reference to FIG. 3, in accordance with an embodiment of the present invention, the plurality 350 of nanowires may be grown on the substrate 304 by depositing gold (Au), or another catalyst, in an amount sufficient to cause the formation of nuclei on the surface of the substrate 304, but insufficient to coalesce into a continuous film across the surface of the substrate 304, for example, a Si substrate. If a flux of Si atoms is then created by evaporation, molecular beam epitaxy (MBE), chemical vapor deposition (CVD), sputtering or other thin-film deposition technique at a favorable temperature, for example, a temperature near the eutectic temperature of Si and Au, Si will transport to the bottom of the Au nuclei and grow a nanowire, for example, nanowire 310, about perpendicular to the substrate 304. The composition of the nanowire, for example, nanowire 310, can be modulated by controlling the composition of the flux of atoms to the substrate 304, for example, a Si substrate, by adding an alloying constituent such as Ge to the flux stream, by which the composition of the growing portion of the nanowire, for example, nanowire 310, can be altered. Depending upon which side of the SHTED 301 is to be used as the hot end, either a first portion 312 may be grown with the composition of Si or SiₓGe₁₋ₓ; if the hot end is located at the substrate, then the first portion 312 is grown as a SiₓGe₁₋ₓ layer, while if the hot end is at the top of the nanowire 310, then the first portion 312 is grown as a Si layer. If the atomic fraction of Si, x, is between about 0.60 and 0.40, so that SiₓGe₁₋ₓ, has a composition between about Si_{0.40}Ge_{0.60} and about Si_{0.60}Ge_{0.40}, the thickness of the SiₓGe₁₋ₓ layer should be less than about 100 nm to preserve epitaxy with the SiₓGe₁₋ₓ lattice. The sidewalls of the plurality 350 of nanowires may be passivated by known techniques, for example, CVD; and the spaces between the plurality 350 of nanowires may be filled in with a passivating material such as silicon dioxide, SiO₂, which may be deposited by known techniques, for example, CVD. In an embodiment of the present invention, it is also possible to compositionally modulate the growth conditions so as to grow more than a first portion of a first semiconductor material with a first composition and a second portion of a second semiconductor material with a second composition in a TEHU, for example, three portions of semiconductor materials of differing composition may be grown, as in the structure which will next be described.

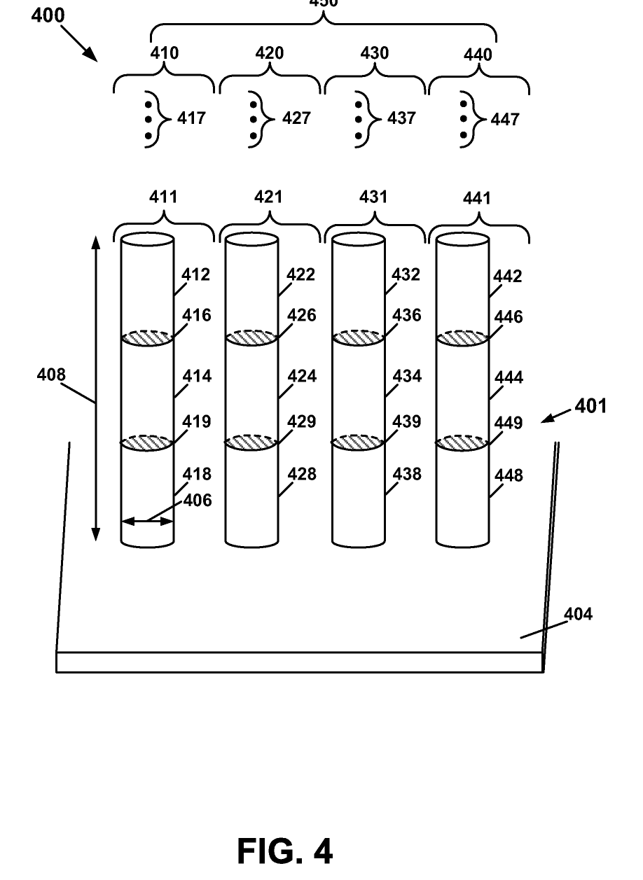

With reference now to FIG. 4, in accordance with an embodiment of the present invention, a perspective view 400 of a SHTED 401 illustrating the functional arrangement a first portion 412, a second portion 414 and a first heterojunction 416 formed between the first portion 412 and the second portion 414 of SHTED 401 in at least one nanowire 410 is shown. The SHTED 401 includes at least one nanowire 410 including at least one TEHU 411. The nanowire 410 is disposed on a substrate 404. The TEHU 411 includes the first portion 412 composed of the first semiconductor material, the second portion 414 composed of a second semiconductor material and the first heterojunction 416 formed between the first portion 412 and the second portion 414. The at least one TEHU, for example, TEHU 411, may further include a third portion 418 composed of a third semiconductor material and a second heterojunction 419 formed between the second portion 414 and the third portion 418. The first portion 412 has a first band gap, the second portion 414 has a second band gap, and the third portion 418 has a third band gap. The first band gap of the first portion 412 is different from the second band gap of the second portion 414; and, the second band gap of the second portion 414 is different from the third band gap of the third portion 418. The second portion 414 includes a second semiconductor material that includes an alloy of the first semiconductor material with an alloying constituent. For example, if the first semiconductor material is Si, and the second semiconductor material is an alloy of Si and Ge, for example, SiₓGe₁₋ₓ, then the band gap of Si, which is 1.12 electron-volts (eV), is greater than the band gap of SiₓGe₁₋ₓ, which depends on the fraction, x, of Si in the alloy and lies between 1.12 eV at high Si content and the band gap of Ge, which is about 0.7 eV, at low Si content; the third semiconductor material may be Ge, which has a band gap of about 0.7 eV. In an embodiment of the present invention, the dimensionless figure of merit of performance for the at least one TEHU 411 of the nanowire 410, defined by ZT, is greater than unity. The first semiconductor material has a first electrical conductivity and a first thermal conductivity; the second semiconductor material has a second electrical current activity and a second thermal conductivity; and, the third semiconductor material has a third electrical conductivity and third thermal conductivity. Similar to the description above of FIGS. 1 and 3, if the second thermal conductivity of the second portion 414 of the nanowire 410 is made sufficiently small, for example, by alloying with a constituent that increases scattering centers for the phonons, then ZT may be made greater than unity. For example, in one embodiment of the present invention, the second portion 414 may be composed of SiₓGe₁₋ₓ, where the Ge provides scattering centers for the phonons. Thus, in an embodiment of the present invention, the second semiconductor material may include an alloy of the first semiconductor material with an alloying constituent such that the second thermal conductivity is less than the first thermal conductivity. Thus, the first semiconductor material may include an elemental semiconductor material, for example, Si. If the first semiconductor material includes Si, then the second semiconductor material may include an alloy of Si and Ge, for example, SiₓGe₁₋ₓ; and, a third semiconductor material, if present as a third portion of a TEHU, may include Ge. The first semiconductor material may also include a compound semiconductor material, for example, gallium arsenide, GaAs. If the first semiconductor material includes GaAs, then the second semiconductor material may include an alloy of aluminum, Al, and GaAs, for example, aluminum gallium arsenide, AlₓGa₁₋ₓAs.

With further reference to FIG. 4, in accordance with an embodiment of the present invention, the nanowire 410 may include additional TEHUs 417, indicated by the ellipsis labeled 417. A plurality of TEHUs includes TEHU 411 in combination with TEHUs 417. The additional TEHUs 417 may be disposed one on top of the other to extend the length of the nanowire 410 along the direction indicated by double-headed arrow, labeled 408, showing the length of the single TEHU 411. The additional TEHUs 417 may replicate the structure of TEHU 411 described above, but without limitation thereto, as the additional TEHUs 417 may have alternative structures. Moreover, SHTED 401 may include a plurality 450 of nanowires. As shown in FIG. 4, the plurality 450 of nanowires includes, without limitation thereto, nanowire 410, nanowire 420, nanowire 430 and nanowire 440. Nanowire 420 includes at least one TEHU 421; the TEHU 421 includes a first portion 422 composed of a first semiconductor material, a second portion 424 composed of a second semiconductor material, a third portion 428 composed of a third semiconductor material, a first heterojunction 426 formed between the first portion 422 and the second portion 424, and a second heterojunction 429 formed between the second portion 424 and the third portion 428. The nanowire 420 may include additional TEHUs 427, indicated by the ellipsis labeled 427. Similarly, nanowire 430 includes at least one TEHU 431; the TEHU 431 includes a first portion 432 composed of a first semiconductor material, a second portion 434 composed of a second semiconductor material, a third portion 438 composed of a third semiconductor material, a first heterojunction 436 formed between the first portion 432 and the second portion 434, and a second heterojunction 439 formed between the second portion 434 and the third portion 438. The nanowire 430 may include additional TEHUs 437, indicated by the ellipsis labeled 437. In addition, nanowire 440 includes at least one TEHU 441; the TEHU 441 includes a first portion 442 composed of a first semiconductor material, a second portion 444 composed of a second semiconductor material, a third portion 448 composed of a third semiconductor material, a first heterojunction 446 formed between the first portion 442 and the second portion 444, and a second heterojunction 449 formed between the second portion 444 and the third portion 448. The nanowire 440 may include additional TEHUs 447, indicated by the ellipsis labeled 447. The additional nanowires, for example, nanowires 420, 430 and 440, may replicate the structure of nanowire 410 as described above, but without limitation thereto. The additional nanowires, for example, nanowires 420, 430 and 440, are likewise disposed on substrate 404. Although the plurality 450 of nanowires are shown as being disposed in a linear array, embodiments of the present invention are not so limited, as the plurality 450 of nanowires may form a three dimensional structure, for example, with additional nanowires into the depth of FIG. 4 (not shown). In addition, the top surfaces of the plurality 450 of nanowires may be provided with an absorber layer (not shown in FIG. 4), similar to absorber layer 106 shown in FIG. 1.

With further reference to FIG. 4, in accordance with an embodiment of the present invention, the TEHU 411 has a diameter 406, which is also the diameter of the nanowire 410. The TEHU 411 also has a length 408. The mean free path of the electron is on the order of 1 nanometer (nm) and the mean free path of the phonon is on the order of 100 nm The diameter of the TEHU 411 is greater than 1 nm but less than 100 nm For example, if the diameter of the TEHU 411 is on the order of 10 to 60 nm, phonons are strongly scattered, for example, by the sidewalls of the TEHU 411, but the electrons go through TEHU 411 relatively unimpeded compared with the phonons. Under these circumstances, the thermal conductivity of the TEHU 411 and correspondingly the nanowire 410 including at least one TEHU, for example, TEHU 411, will be greatly diminished compared with the electrical conductivity of the TEHU 411 and correspondingly the nanowire 410. Moreover, the nanowire 410 including at least one TEHU 411 will have a further diminished thermal conductivity beyond the effect of the diameter of the nanowire 410 for scattering phonons due to the structure of the TEHU 411 including the second portion 414 composed of an alloy that further diminishes the thermal conductivity of the TEHU 411 and correspondingly the nanowire 410 including TEHU 411. Therefore, in an embodiment of the present invention, the dimensionless figure of merit ZT is further improved by a structure including nanowires having a critical diameter small enough to impede phonon transport without substantially hindering electron transport, but further including at least one TEHU, for example, TEHU 411, including a second portion 414 composed of an alloy that further diminishes the thermal conductivity, as described above. The critical diameter of the nanowire to obtain this diminution of thermal conductivity, for example, nanowire 410, is between about 1 nm and 100 nm In addition, the nanowire, for example, nanowire 410, can be grown to an overall length of about 1 to 2 μm.

With further reference to FIG. 4, in accordance with an embodiment of the present invention, the plurality 450 of nanowires may be grown on the substrate 404 by depositing Au, or another catalyst, in an amount sufficient to cause the formation of nuclei on the surface of the substrate 404, but insufficient to coalesce into a continuous film across the surface of the substrate 404, for example, a Si substrate. As previously described, if a flux of Si atoms is then created by evaporation, MBE, CVD, sputtering or other thin-film deposition technique at a favorable temperature, for example, a temperature near the eutectic temperature of Si and Au, Si will transport to the bottom of the Au nuclei and grow a nanowire, for example, in nanowire 410, about perpendicular to the substrate 404. The composition of the nanowire, for example, nanowire 410, can be modulated by controlling the composition of the flux of atoms to the substrate 404, for example, a Si substrate, by adding in alloying constituent such as Ge to the flux stream, by which the composition of the growing portion of the nanowire, for example, nanowire 410, can be altered. Depending upon which side of the SHTED 401 is to be used as the hot end, either a first portion 412 may be grown with the composition of Si or Ge; if the hot end is located at the substrate the first portion 412 is grown as a Ge layer, but if the hot end is at the top of the nanowire 410 the first portion 412 is grown as a Si layer. The SiₓGe₁₋ₓ, which lies between the Si and Ge layers, may be grown by adding Ge to the flux stream if the portion adjacent to the substrate 404 is a Si substrate; or, alternatively, may be grown by adding Si if the portion adjacent to the substrate is Ge, for example, if the substrate 404 is Ge substrate. If the atomic fraction of Si, x, is between about 0.60 in 0.40, so that SiₓGe₁₋ₓ, has a composition between about Si_{0.40}Ge_{0.60} and about Si_{0.60}Ge_{0.40}, the thickness of the SiₓGe₁₋ₓ layer should be less than about 100 nm to preserve epitaxy with the SiₓGe₁₋ₓ lattice. As previously described, the sidewalls of the plurality 450 of nanowires may be passivated by known techniques, for example, CVD; and the spaces between the plurality 450 of nanowires may be filled in with a passivating material such SiO₂ which may be deposited by known techniques, for example, CVD. In an embodiment of the present invention, it is also possible to compositionally modulate the growth conditions so as to grow more than a first portion of a first semiconductor material with a first composition, a second portion of a second semiconductor material with a second composition, and a third portion of a third semiconductor material with a third composition in a TEHU, for example, more than three portions of semiconductor materials of differing composition may be grown, as in the structure which will next be described.

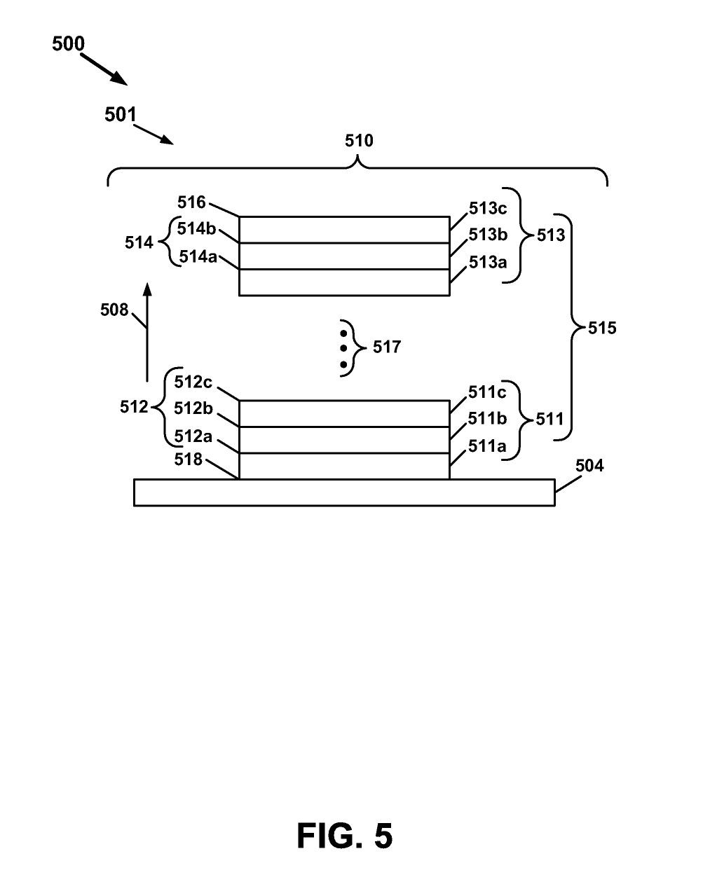

With reference now to FIG. 5, in accordance with an embodiment of the present invention, a cross-sectional elevation view 500 of a SHTED 501 illustrating the functional arrangement of portions, for example, a first portion 511a, a second portion 511b, and a third portion 511c, and heterojunctions 512, for example, a first heterojunction 512a, a second heterojunction 512b, and a third heterojunction 512c, in a TEHU 511 of a n-layer, for example, shown as a trilayer, of a plurality of n-layers of a multilayer structure 515 in at least one nanowire 510 is shown. The SHTED 501 includes at least one nanowire 510 including the multilayer structure 515. The nanowire 510 is disposed on a substrate 504. The multilayer structure 515, also known by the term of art “superlattice,” includes a plurality of n-layers, for example, bi-layers, trilayers or quadrilayers, without limitation thereto. An n-layer of the plurality of n-layers includes a TEHU, for example, TEHU 511. The TEHU 511 includes, without limitation thereto, at least the first portion 511a composed of a first semiconductor material and the second portion 511b composed of a second semiconductor material and the first heterojunction 512a formed between the first portion 511a and the second portion 511b. As shown in FIG. 5, the first n-layer is a trilayer including TEHU 511; TEHU 511 includes the first portion 511a, the second portion 511b and the third portion 511c. For example, the TEHU 511 may further include a third portion 511c composed of a third semiconductor material and a second heterojunction 512b formed between the second portion 511b and the third portion 511c. As the multilayer is composed of a plurality of n-layers, a third heterojunction 512c may be formed between the third portion 511c and a first portion (not shown) of a next adjacent n-layer of the n-layers of additional TEHUs 517, indicated by the ellipsis labeled 517. Similarly, a junction 518 is formed between the first portion 511a of the TEHU 511 and the substrate 504; but, if the substrate 504 differs in composition from the first semiconductor material of the first portion 511a of the TEHU 511, the junction 518 is also a heterojunction.

With further reference to FIG. 5, in accordance with an embodiment of the present invention, the first portion 511a has a first band gap, the second portion 511b has a second band gap and there may be a third portion 511c that has a third band gap. The first band gap of the first portion 511a is different from the second band gap of the second portion; and, the second band gap of the second portion 511b may be different from the third band gap of the third portion 511c. The second portion 511b includes a second semiconductor material that includes an alloy of the first semiconductor material with an alloying constituent. For example, if the first semiconductor material is Si, and the second semiconductor material is an alloy of Si and Ge, for example, SiₓGe₁₋ₓ, then the band gap of Si, which is 1.12 electron-volts (eV), is greater than the band gap of SiₓGe₁₋ₓ, which depends on the fraction, x, of Si in the alloy and lies between 1.12 eV at high Si content and the band gap of Ge, which is about 0.7 eV, at low Si content; the third semiconductor material may be Ge, which has a band gap of about 0.7 eV. In an embodiment of the present invention, the dimensionless figure of merit of performance for the at least one TEHU 511 of the nanowire 510, defined by ZT, is greater than unity. The first semiconductor material has a first electrical conductivity and a first thermal conductivity; the second semiconductor material has a second electrical current activity and a second thermal conductivity; and, the third semiconductor material has a third electrical conductivity and third thermal conductivity. Similar to the description above of FIGS. 1, 3 and 4, if the second thermal conductivity of the second portion 511b of the nanowire 510 is made sufficiently small, for example, by alloying with a constituent that increases scattering centers for the phonons, then ZT may be made greater than unity. For example, in one embodiment of the present invention, the second portion 511b may be composed of SiₓGe₁₋ₓ, where the Ge provides scattering centers for the phonons. Thus, in an embodiment of the present invention, the second semiconductor material may include an alloy of the first semiconductor material with an alloying constituent such that the second thermal conductivity is less than the first thermal conductivity. Thus, the first semiconductor material may include an elemental semiconductor material, for example, Si. If the first semiconductor material includes Si, then the second semiconductor material may include an alloy of Si and Ge, for example, SiₓGe₁₋ₓ; and, a third semiconductor material, if present as a third portion in a TEHU of an n-layer, may include Ge. The first semiconductor material may also include a compound semiconductor material, for example, gallium arsenide, GaAs. If the first semiconductor material includes GaAs, then the second semiconductor material may include an alloy of aluminum, Al, and GaAs, for example, aluminum gallium arsenide, AlₓGa₁₋ₓAs.

With further reference to FIG. 5, in accordance with an embodiment of the present invention, the nanowire 510 may include additional TEHUs 517, indicated by the ellipsis labeled 517. As shown in FIG. 5, the last n-layer is a trilayer including TEHU 513; TEHU 513 includes, a first portion 513a, a second portion 513b, and a third portion 513c. The TEHU 513 includes, without limitation thereto, at least the first portion 513a composed of a first semiconductor material and the second portion 513b composed of a second semiconductor material and a first heterojunction 514a formed between the first portion 513a and the second portion 513b. The TEHU 513 may further include a third portion 513c composed of a third semiconductor material and a second heterojunction 514b formed between the second portion 513b and the third portion 513c. The first portion 513a has a first band gap, the second portion 513b has a second band gap and the third portion 513c has a third band gap. The first band gap of the first portion 513a is different from the second band gap of the second portion 513b; and, the second band gap of the second portion 513b is different from the third band gap of the third portion 513c. The second portion 513b includes a second semiconductor material that includes an alloy of the first semiconductor material with an alloying constituent. Moreover, a junction 516 is formed between the third portion 513c of the TEHU 513 and a overlayer (not shown), similar to absorber layer 106 of FIG. 1, or alternatively a conductive overlayer such as polysilicon deposited to provide electrical contact with the top of nanowire 510; but, if the overlayer differs in composition from the third semiconductor material of the third portion 513c of the TEHU 513, the junction 516 is also a heterojunction. The structure of the last TEHU 513 and the additional TEHUs 517 replicate the structure and properties of the TEHU 511 as described above.

With further reference to FIG. 5, in accordance with an embodiment of the present invention, a plurality of TEHUs includes TEHU 511, TEHU 513 and the additional TEHUs 517, as indicated by the ellipsis labeled 517. The additional TEHUs 517 may be disposed one on top of the other to extend the length of the nanowire 510 along the direction indicated by the arrow, labeled 508. The additional TEHUs 517 replicate the structure of TEHU 511 described above to provide a multilayer structure, know as a superlattice. Moreover, SHTED 501 may include a plurality of nanowires (not shown, but similar to plurality 450 of FIG. 4). The additional nanowires may replicate the structure of nanowire 510, similar to the replication of nanowire 410 as described above. The additional nanowires are likewise disposed on substrate 504. The plurality of nanowires may form a three dimensional structure, similar to three dimensional structure described for FIG. 4. In addition, the top surfaces of the plurality of nanowires may be provided with an absorber layer (not shown in FIG. 4 or 5), similar to absorber layer 106 shown in FIG. 1. In fabricating the superlattice, each TEHU corresponds to an n-layer which is periodically replicated throughout the structure. For example, in an embodiment of the present invention, the multilayer may include a plurality of m bilayers of Si and SiₓGe₁₋ₓ, given by the formulae: [Si/SiₓGe₁₋ₓ]ₘ, or alternatively, [Siₓ Ge₁₋ₓ/Si]ₘ, where m indicates the number of periods of the bilayer replicated in the structure. For example, in an alternative embodiment of the present invention, the multilayer may include a plurality of m trilayers of Si, SiₓGe₁₋ₓ and Ge, given by the formulae: [Si/SiₓGe₁₋ₓ/Ge]ₘ, or alternatively, [Ge/SiₓGe₁₋ₓ/Si]ₘ, where m indicates the number of periods of the trilayer replicated in the structure.

With reference now to FIG. 6, in accordance with an embodiment of the present invention, a cross-sectional elevation view and schematic 600 of a SHTED 601 is shown. FIG. 6 illustrates the functional arrangement of a first portion 612, a second portion 614 and a heterojunction 616 formed between the first portion 612 and the second portion 614 of the SHTED 601. The SHTED 601 may include at least one thermoelectric heterostructure unit (TEHU) 610 which includes the first portion 612 composed of a first semiconductor material, the second portion 614 composed of a second semiconductor material and the heterojunction 616 formed between the first portion 612 and the second portion 614. The second semiconductor material is disposed as at least one sub-micron patch of the second portion 614, as is previously described in the discussions of FIGS. 2A-2E. Alternatively, the first semiconductor material may also be disposed as a sub-micron patch of the first portion such that the sub-micron patch of the first portion and the sub-micron patch of the second portion form at least a portion of a nanowire, as is previously described in the discussions of FIGS. 3, 4 and 5. A dimensionless figure of merit of performance for the SHTED 601, defined by ZT, is greater than unity. The TEHU 610 includes the first portion 612 composed of a first semiconductor material, the second portion 614 composed of a second semiconductor material and the heterojunction 616 formed between the first portion 612 and the second portion 614. The first semiconductor material has a first electrical conductivity and a first thermal conductivity; and, the second semiconductor material has a second electrical conductivity and a second thermal conductivity. The second semiconductor material includes an alloy of the first semiconductor material with an alloying constituent. The second semiconductor material may include an alloy of the first semiconductor material with the alloying constituent such that the second thermal conductivity is less than the first thermal conductivity.

With further reference to FIG. 6 and as shown in FIG. 6, in accordance with an embodiment of the present invention, the SHTED 601 is configured as a TEC. However, embodiments of the present invention are not limited to a SHTED 601 configured as a TEC, rather the SHTED 601 may be configured as a device selected from the group consisting of a TEG and a TEC. The SHTED 601, configured as a TEC, may include an absorber layer 606, the TEHU 610 and a substrate 604. The absorber layer 606 may be composed of a “black-body” absorbing material, such as a “black-body” polymer, that is disposed on the cold end of the TEHU 610. The substrate 604 may be disposed at the hot end of the TEHU 610. As shown in FIG. 6, heat flux 620 that is pumped into and is emitted from the substrate 604 may raise the temperature of the substrate 604 and lower the temperature of the absorber layer 606 in contact with the TEHU 610 by several tens of degrees C. with respect to the ambient temperature. For example, in one embodiment of the present invention, the second portion 614 is composed of p+-doped silicon germanium, SiₓGe₁₋ₓ, in which the majority carriers are holes and the minority carriers are electrons, for example, electron 621 having an associated electron current 622 and hole 623 having an associated hole current 624; and, the first portion 612 is composed of intrinsic silicon, Si, in which the carriers may be equal in numbers of both holes and electrons, for example, electron 625 having an associated electron current 626 and hole 627 having an associated hole current 628. A current 638 driven through the TEHU 610 gives rise to a current of the holes, for example, hole current 624, from the cold end of the TEHU 610 to the hot end of the TEHU 610. If a first electrical contact 630 is made to the hot end of the TEHU 610 and a second electrical contact 642 is made to the cold end of the TEHU 610, and if a first electrical lead 634 is provided to the hot end of the TEHU 610 and a second electrical lead 636 is provided to the cold end of the TEHU 610, the current 638, I, is made to flow through the TEHU 610 by a voltage source 640, which has voltage, V, which causes a transport of heat from the cold end located at the absorber layer 606 to the hot end located at the substrate 604. As one end of the TEC is hot and the other end is cold, the TEC may be operated as a thermoelectric heater (TEH). If the polarity of the current 638 and the voltage source 640 are reversed, the TEH will pump heat towards the opposite end of the TEHU 610 from that shown in FIG. 6.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It may be intended that the scope of the invention be defined by the claims appended hereto and their equivalents.

1. A semiconductor heterostructure thermoelectric device comprising:
at least one thermoelectric heterostructure unit, said thermoelectric heterostructure unit comprising:
a first portion composed of a first semiconductor material, said first semiconductor material having a first electrical conductivity and a first thermal conductivity; and
a second portion composed of a second semiconductor material and forming a heterojunction with said first portion, said second semiconductor material having a second electrical conductivity and a second thermal conductivity, said second semiconductor material disposed as at least one sub-micron patch of said second portion, said second semiconductor material comprising an alloy of said first semiconductor material with an alloying constituent; and
wherein a dimensionless figure of merit of performance for said semiconductor heterostructure thermoelectric device defined by ZT, is greater than unity.

2. The device of claim 1, wherein said device is configured as a thermoelectric generator including an absorber layer, said absorber layer disposed on a hot end of said thermoelectric heterostructure unit.

3. The device of claim 1, wherein said first semiconductor material is disposed as a sub-micron patch of said first portion; and
wherein said sub-micron patch of said first portion and said sub-micron patch of said second portion form at least a portion of a nanowire.

4. The device of claim 1, wherein said first electrical conductivity is greater than said second electrical conductivity.

5. The device of claim 1, wherein said second semiconductor material comprises an alloy of said first semiconductor material with said alloying constituent such that said second thermal conductivity is less than said first thermal conductivity.

6. The device of claim 1, wherein said first semiconductor material comprises silicon and said second semiconductor material comprises an alloy of silicon and germanium.

7. The device of claim 1, wherein said first semiconductor material comprises gallium arsenide and said second semiconductor material comprises an alloy of aluminum and gallium arsenide.

8. The device of claim 1, wherein said device is configured as a thermoelectric cooler.

9. A semiconductor heterostructure thermoelectric device comprising:
at least one nanowire comprising at least one thermoelectric heterostructure unit, said thermoelectric heterostructure unit comprising:
a first portion composed of a first semiconductor material, a second portion composed of a second semiconductor material and a first heterojunction formed between said first portion having a first band gap and said second portion having a second band gap;
wherein said first band gap of said first portion is different from said second band gap of said second portion;
wherein said second portion comprises a second semiconductor material that comprises an alloy of said first semiconductor material with an alloying constituent; and
wherein a dimensionless figure of merit of performance for said at least one thermoelectric heterostructure unit, defined by ZT, is greater than unity.

10. The device of claim 9, wherein said first semiconductor material has a first electrical conductivity and a first thermal conductivity;
wherein said second semiconductor material has a second electrical conductivity and a second thermal conductivity; and
wherein said second semiconductor material comprises an alloy of said first semiconductor material with said alloying constituent such that said second thermal conductivity is less than said first thermal conductivity.

11. The device of claim 9, wherein said at least one thermoelectric heterostructure unit further comprises:
a third portion composed of a third semiconductor material and a second heterojunction formed between said second portion and said third portion having a third band gap; and
wherein said second band gap of said second portion is different from said third band gap of said third portion.

12. The device of claim 11, wherein said first semiconductor material comprises silicon, said second semiconductor material comprises an alloy of silicon and germanium and said third semiconductor material comprises germanium.

13. A semiconductor heterostructure thermoelectric device comprising:
at least one nanowire comprising a multilayer structure;
said multilayer structure comprising a plurality of n-layers, an n-layer of said plurality of n-layers comprising a thermoelectric heterostructure unit, said thermoelectric heterostructure unit comprising:
at least a first portion composed of a first semiconductor material, and a second portion composed of a second semiconductor material and a first heterojunction formed between said first portion having a first band gap and said second portion having a second band gap;
wherein said first band gap of said first portion is different from said second band gap of said second portion;
wherein said second portion comprises a second semiconductor material that comprises an alloy of said first semiconductor material with an alloying constituent; and
wherein a dimensionless figure of merit of performance for said thermoelectric heterostructure unit, defined by ZT, is greater than unity.

14. The device of claim 13, wherein said first semiconductor material has a first electrical conductivity and a first thermal conductivity;
wherein said second semiconductor material has a second electrical conductivity and a second thermal conductivity; and
wherein said second semiconductor material comprises an alloy of said first semiconductor material with said alloying constituent such that said second thermal conductivity is less than said first thermal conductivity.

15. The device of claim 13, wherein said thermoelectric heterostructure unit further comprises:
a third portion composed of a third semiconductor material and a second heterojunction formed between said second portion and said third portion having a third band gap; and
wherein said second band gap of said second portion is different from said third band gap of said third portion.
